(19) United States
(12) Patent Application Publication
(10) Pub. No.: US 2026/0086452 A1
(43) Pub. Date: Mar. 26, 2026

(54) IMPRINT INK AND IMPRINT METHOD USING THE SAME

(71) Applicant: ASUSTEK COMPUTER INC., TAIPEI (TW)

(72) Inventors: Guo-Lin YANG, TAIPEI (TW); Po-Wen HUANG, TAIPEI (TW); Yu-Chun YANG, TAIPEI (TW); Er-Bao NIU, TAIPEI (TW); Tao CHEN, TAIPEI (TW)

(21) Appl. No.: 18/959,951

(22) Filed: Nov. 26, 2024

(30) Foreign Application Priority Data
Sep. 20, 2024 (TW) 113135770

(51) Int. Cl. G03F 7/00; C09D 11/107

(52) U.S. Cl. CPC G03F 7/0002; C09D 11/107

(57) ABSTRACT

An imprint ink is provided. The imprint ink includes 65 wt % to 70 wt % of polymerizable prepolymer, 7 wt % to 13 wt % of photosensitive monomer, 0.5 wt % to 1.5 wt % of photoinitiator, 8 wt % to 17 wt % of abrasion-resistant acrylic mixed reaction resin, and an auxiliary. An imprint method is further provided. First, a substrate is provided. Then, an imprint ink layer is formed on the substrate by using the imprint ink. Next, semi-curing processing is performed on the imprint ink layer, to form a semi-cured imprint ink layer. Then, the semi-cured imprint ink layer is shaped by using a mold, to form a semi-cured imprint ink contour layer. Finally, full curing processing is performed on the semi-cured imprint ink contour layer, to form an imprint pattern layer on the substrate.

### CROSS-REFERENCE TO RELATED APPLICATION

This application claims the priority benefit of Taiwan Application Serial No. 113135770, filed on Sep. 20, 2024. The entirety of the above-mentioned patent application is hereby incorporated by reference herein and made a part of the specification.

### BACKGROUND OF THE INVENTION

### FIELD OF THE INVENTION

The disclosure relates to the technical field of imprint, and in particular, to an imprint ink used for nano imprint and an imprint method using the same.

### Description of the Related Art

A nano imprint lithography (NIL) technology is a surface processing technology, and is suitable for rapid and large-scale microstructure fabrication on a target workpiece.

However, a conventional nano imprint lithography technology is limited to a used imprint ink, which easily leads to disadvantages such as a poor physical property of a surface film layer, difficulty in cleaning, and a poor anti-fouling capability.

Specifically, a surface film layer formed in the conventional nano imprint lithography technology withstands less than 10,000 times of abrasion in an abrasion test with a 200 g load and wool felt, less than 300 times of abrasion in an abrasion test with a 200 g load and rolls of wear test paper (RCA), less than 600 times of abrasion in an abrasion test with a 200 g load and an eraser, and less than 600 times of abrasion in an abrasion test with a 200 g load and alcohol. In addition, a contact angle on a surface is less than 80°.

### BRIEF SUMMARY OF THE INVENTION

The disclosure provides an imprint ink. The imprint ink includes 65 wt % to 70 wt % of polymerizable prepolymer, 7 wt % to 13 wt % of photosensitive monomer, 0.5 wt % to 1.5 wt % of photoinitiator, 8 wt % to 17 wt % of abrasion-resistant acrylic mixed reaction resin, and an auxiliary.

By using the foregoing imprint ink, the disclosure provides an imprint method, including the following steps. First, a substrate is provided. Then, an imprint ink layer is formed on the substrate by using the imprint ink. Next, semi-curing processing is performed on the imprint ink layer, to form a semi-cured imprint ink layer. Then, the semi-cured imprint ink layer is shaped by using a mold, to form a semi-cured imprint ink contour layer. Finally, full curing processing is performed on the semi-cured imprint ink contour layer, to form an imprint pattern layer on the substrate.

A main difference between the disclosure and a conventional imprint technology lies in a difference in physical properties of a surface film layer formed through imprint. A film layer formed through conventional nano imprint withstands less than 10,000 times of abrasion in an abrasion test with a 200 g load and wool felt, less than 300 times of abrasion in an abrasion test with a 200 g load and rolls of wear test paper (RCA), less than 600 times of abrasion in an abrasion test with a 200 g load and an eraser, and less than 600 times of abrasion in an abrasion test with a 200 g load and alcohol. In addition, a contact angle on a surface is less than 80°.

In comparison, the imprint pattern layer in the disclosure withstands more than 100,000 times of abrasion in an abrasion test with a 500 g load and wool felt, more than 1,000 times of abrasion in an abrasion test with a 500 g load and rolls of wear test paper, more than 15,000 times of abrasion in an abrasion test with a 500 g load and an eraser, and more than 15,000 times of abrasion in an abrasion test with a 500 g load and alcohol. In addition, a contact angle on a surface is greater than 115°. Therefore, compared with that the surface film layer formed in the conventional imprint technology has disadvantages of being easy to be contaminated on a surface, difficult to clean, not resistant to a fingerprint, and prone to cause a scratch on a surface of an object due to insufficient abrasion resistance, the imprint pattern layer formed by using the imprint ink and the imprint method provided in the disclosure has advantages of being not easy to be contaminated, easy to clean, anti-fingerprint, good in abrasion resistance, and able to effectively prevent a surface of an object from being scratched.

### BRIEF DESCRIPTION OF THE DRAWINGS

FIG. 1 is a flowchart of an imprint method according to an embodiment of the disclosure; and

FIG. 2 to FIG. 5 are schematic structural diagrams corresponding to the imprint method in FIG. 1.

### DETAILED DESCRIPTION OF THE EMBODIMENTS

More detailed descriptions of specific embodiments of the disclosure are provided below with reference to the accompanying drawings. The features and advantages of the disclosure are described more clearly according to the following description and claims. It is to be noted that all of the drawings use very simplified forms and imprecise proportions, only being used for assisting in conveniently and clearly explaining the objective of the embodiments of the disclosure.

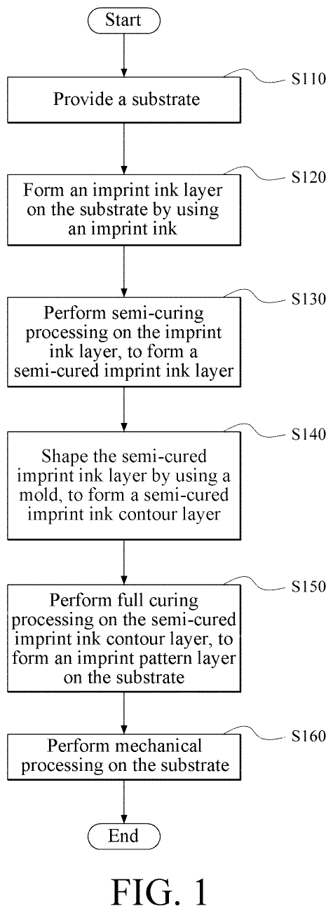

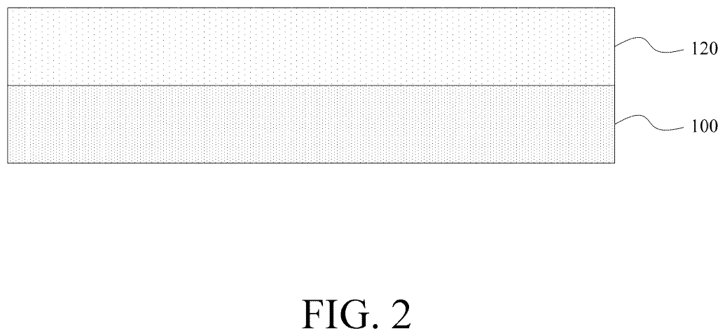

FIG. 1 is a flowchart of an imprint method according to an embodiment of the disclosure. FIG. 2 to FIG. 5 are schematic structural diagrams corresponding to the imprint method in FIG. 1. The imprint method is a nano imprint method, and a feature thereof is using a mold with a nano-scale pattern to transfer a pattern onto an object surface.

As shown in FIG. 1, the imprint method in this embodiment includes the following steps.

First, referring to FIG. 2, as described in step S110, a substrate 100 is provided. A size and an appearance of the substrate 100 are determined based on an actual design requirement.

The substrate 100 is a lightweight alloy, such as an aluminum alloy, a magnesium aluminum alloy, or a lithium magnesium alloy, commonly used in a structural member. Another metallic material, or even a non-metallic polymer or ceramic material, is also applicable to the disclosure.

Then, referring to FIG. 2, as described in step S120, an imprint ink layer 120 is formed on the substrate 100 by using an imprint ink. An appearance feature such as a color or gloss of the imprint ink selected in this step is determined based on design of an imprint pattern. In an embodiment, imprint inks in different colors are coated on the substrate 100, to present an imprint pattern in different colors.

The imprint ink used in this embodiment includes 65 wt % to 70 wt % of polymerizable prepolymer, 7 wt % to 13 wt % of photosensitive monomer, 0.5 wt % to 1.5 wt % of photoinitiator, 8 wt % to 17 wt % of abrasion-resistant acrylic mixed reaction resin, and an auxiliary.

In an embodiment, the foregoing abrasion-resistant acrylic mixed reaction resin is prepared by mixing butyl methacrylate (BMA) or methyl methacrylate copolymer (MMA copolymer) into acrylic resin to provide an effect such as being abrasion-resistant or anti-fingerprint.

In an embodiment, the foregoing auxiliary includes a leveling agent, a polymerisation inhibitor, and a dispersant, to ensure uniform composition of the imprint ink and provide appropriate viscosity to satisfy a processing requirement. Amounts of the leveling agent, the polymerisation inhibitor, and the dispersant are adjusted based on an actual requirement.

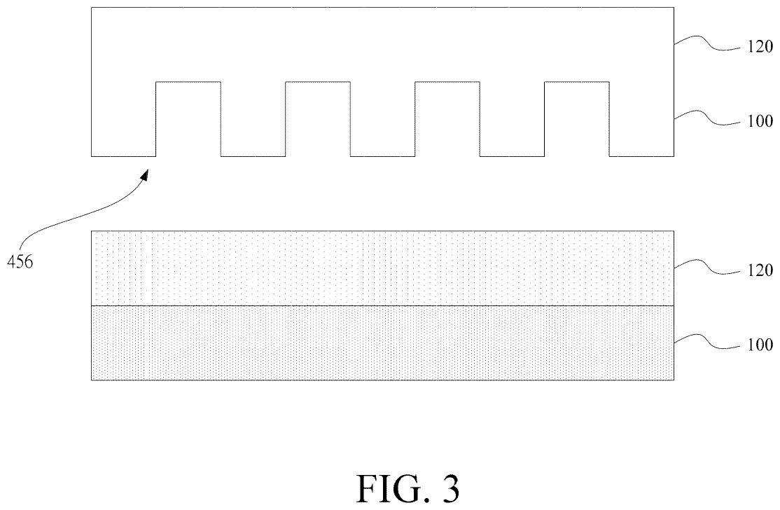

Next, as described in step S130, referring to FIG. 3, semi-curing processing is performed on the imprint ink layer 120, to form a semi-cured imprint ink layer 140. The semi-curing processing is light curing processing or thermal curing processing. Through the semi-curing processing, the imprint ink layer 120 originally presented as a fluid is converted into the semi-cured imprint ink layer 140 presented in a glue state.

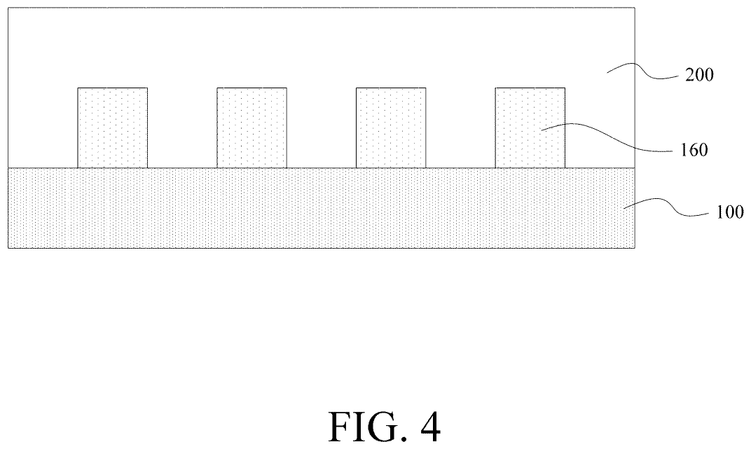

Then, referring to FIG. 3 and FIG. 4, as described in step S140, the semi-cured imprint ink layer 140 is shaped by using a mold 200, to form a semi-cured imprint ink contour layer 160. That is, a pressure is applied to the mold 200 to shape the semi-cured imprint ink layer 140.

A surface of the mold 200 includes a micron-scale or nano-scale pattern structure 220. Through step S140, the micron-scale or nano-scale pattern structure 220 on the mold 200 is transferred onto the substrate 100. The pattern structure 220 of the surface of the mold 200 shown in the figure has only a single depth. In another embodiment, a pattern structure with various depth variations is alternatively formed on the mold 200. In this way, a semi-cured imprint ink contour layer 160 with varying thickness is formed by using the mold 200, to provide a three-dimensional surface effect.

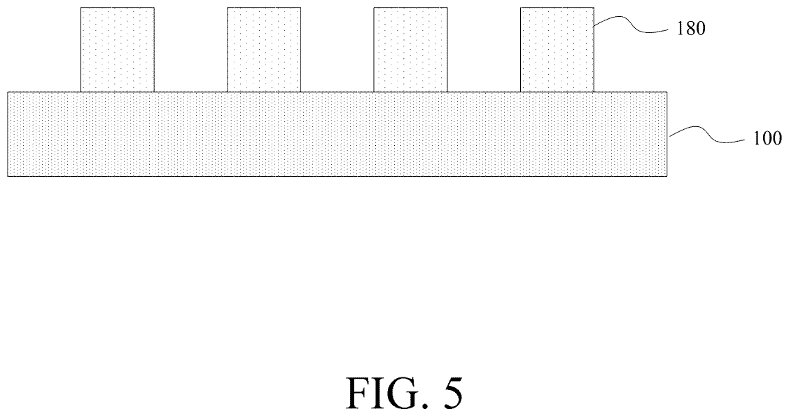

Subsequently, referring to FIG. 5, after the mold 200 is removed, as described in step S150, full curing processing is performed on the semi-cured imprint ink contour layer 160, to form an imprint pattern layer 180 on the substrate 100. The full curing processing helps to ensure a function (in an embodiment, easy to clean or anti-fouling) and a physical property (in an embodiment, hardness or abrasion resistance) of a surface film layer (in an embodiment, the imprint pattern layer 180 formed in this embodiment) of the substrate 100.

The full curing processing is light curing processing or thermal curing processing. By using the light curing processing as an example, light-source energy used in the full curing processing is roughly between 1500 mj and 2000 mj.

In addition, in the foregoing embodiment, the full curing processing is performed after the mold 200 is removed. In another embodiment, in a case that the mold 200 or the substrate 100 is made of a transparent material, the full curing processing is alternatively performed directly through the mold 200 or the substrate 100 when the mold 200 is pressed onto the substrate 100.

In a case that both the semi-curing processing and the full curing processing are light curing processing, light-source energy for the semi-curing processing is not greater than 40% of the light-source energy for the full curing processing. If the light-source energy used in the full curing processing is roughly between 1500 mj and 2000 mj, an upper limit of the light-source energy used in the semi-curing processing is between 600 mj and 800 mj.

Subsequently, as described in step S160, mechanical processing is performed on the substrate 100, to form a final desired shape. The foregoing mechanical processing includes, in an embodiment, a physical processing method such as stamping or computer numerical control (CNC) processing.

A main difference between the disclosure and a conventional imprint technology lies in a difference in physical properties of a surface film layer formed through imprint. A film layer formed through conventional nano imprint withstands less than 10,000 times of abrasion in an abrasion test with a 200 g load and wool felt, less than 300 times of abrasion in an abrasion test with a 200 g load and rolls of wear test paper (RCA), less than 600 times of abrasion in an abrasion test with a 200 g load and an eraser, and less than 600 times of abrasion in an abrasion test with a 200 g load and alcohol. In addition, a contact angle on a surface is less than 80°.

In comparison, the imprint pattern layer 180 in the disclosure withstands more than 100,000 times of abrasion in an abrasion test with a 500 g load and wool felt, more than 1,000 times of abrasion in an abrasion test with a 500 g load and rolls of wear test paper, more than 15,000 times of abrasion in an abrasion test with a 500 g load and an eraser, and more than 15,000 times of abrasion in an abrasion test with a 500 g load and alcohol. In addition, a contact angle on a surface is greater than 115°. Therefore, compared with that the surface film layer formed in the conventional imprint technology has disadvantages of being easy to be contaminated on a surface, difficult to clean, not resistant to a fingerprint, and prone to cause a scratch on a surface of an object due to insufficient abrasion resistance, the imprint pattern layer 180 formed by using the imprint ink and the imprint method provided in the disclosure has advantages of being not easy to be contaminated, easy to clean, anti-fingerprint, good in abrasion resistance, and able to effectively prevent a surface of an object from being scratched.

The above is merely exemplary embodiments of the disclosure, and does not constitute any limitation on the disclosure. Any form of equivalent replacements or modifications to the technical means and technical content disclosed in the disclosure made by a person skilled in the art without departing from the scope of the technical means of the disclosure still fall within the content of the technical means of the disclosure and the protection scope of the disclosure.

What is claimed is:

1. An imprint ink, comprising:
65 wt % to 70 wt % of polymerizable prepolymer;
7 wt % to 13 wt % of photosensitive monomer;
0.5 wt % to 1.5 wt % of photoinitiator;
8 wt % to 17 wt % of abrasion-resistant acrylic mixed reaction resin; and
an auxiliary.

2. The imprint ink according to claim 1, wherein the auxiliary comprises a leveling agent, a polymerisation inhibitor, and a dispersant.

3. The imprint ink according to claim 1, wherein the abrasion-resistant acrylic mixed reaction resin comprises butyl methacrylate (BMA) or methyl methacrylate copolymer (MMA copolymer).

4. An imprint method, comprising:
providing a substrate;
forming an imprint ink layer on the substrate by using an imprint ink;
performing semi-curing processing on the imprint ink layer, to form a semi-cured imprint ink layer;
shaping the semi-cured imprint ink layer by using a mold, to form a semi-cured imprint ink contour layer; and
performing full curing processing on the semi-cured imprint ink contour layer, to form an imprint pattern layer on the substrate.

5. The imprint method according to claim 4, wherein the imprint method is a nano imprint method.

6. The imprint method according to claim 4, wherein the semi-curing processing is light curing processing or thermal curing processing.

7. The imprint method according to claim 4, wherein the full curing processing is light curing processing or thermal curing processing.

8. The imprint method according to claim 4, wherein both the semi-curing processing and the full curing processing are light curing processing, and light-source energy for the semi-curing processing is not greater than 40% of light-source energy for the full curing processing.

9. The imprint method according to claim 4, further comprising: performing mechanical processing on the substrate after the imprint pattern layer is formed.

10. The imprint method according to claim 4, wherein the imprint ink comprises 65 wt % to 70 wt % of polymerizable prepolymer, 7 wt % to 13 wt % of photosensitive monomer, 0.5 wt % to 1.5 wt % of photoinitiator, 8 wt % to 17 wt % of abrasion-resistant acrylic mixed reaction resin, and an auxiliary.
